(19) United States
(12) Patent Application Publication
(10) Pub. No.: US 2018/0277713 A1
(43) Pub. Date: Sep. 27, 2018

(54) RED LIGHT EMITTING DIODES HAVING AN INDIUM GALLIUM NITRIDE TEMPLATE LAYER AND METHOD OF MAKING THEREOF

(71) Applicant: GLO AB, Lund (SE)

(72) Inventors: Rafal CIECHONSKI, Lund (SE); Fariba DANESH, Pleasanton, CA (US); Nathan GARDNER, Sunnyvale, CA (US); Benjamin LEUNG, Sunnyvale, CA (US); Miao-Chan TSAI, Sunnyvale, CA (US)

(21) Appl. No.: 15/464,641

(22) Filed: Mar. 21, 2017

(51) Int. Cl. H01L 33/00; H01L 21/02; H01L 33/24; H01L 33/32

(52) U.S. Cl. CPC H01L 33/0075; H01L 21/02389; H01L 21/02513; H01L 33/32; H01L 21/0254; H01L 21/02603; H01L 33/24

(57) ABSTRACT

A growth mask layer including an array of apertures therethrough can be formed on a single crystalline gallium nitride layer. Group III nitride nanostructures including gallium nitride or indium gallium nitride nanopyramids or nanowires can be formed through the array of apertures by a selective epitaxy process. An indium gallium nitride material can be deposited by another selective epitaxy process on the Group III nitride nanostructures until a continuous indium gallium nitride template layer is formed. The continuous indium gallium nitride template layer has a dislocation density that decreases with distance from the growth mask layer. Red light emitting diodes can be formed over the continuous indium gallium nitride template layer with higher efficiency due the relatively large lattice constant of the continuous indium gallium nitride template layer.

### FIELD

The present invention relates to light emitting diodes, and particularly to red light emitting diodes employing an indium gallium nitride template layer and methods of fabricating the same.

### BACKGROUND

For light emitting devices, such as light emitting diodes (LED), the emission wavelength is determined by the band gap of the active region of the LED together with thickness determined confinement effects. Often the active region includes one or more bulk semiconductor layers or quantum wells (QW). For III-nitride based LED devices, such as GaN based devices, the active region (e.g., bulk semiconductor layer or QW well layer) material is preferably ternary, such as InₓGa₁₋ₓN, where 0<x<1.

The band gap of such III-nitride active region is dependent on the amount of In incorporated in the active region. Higher indium incorporation will yield a smaller band gap and thus longer wavelength of the emitted light. As used herein, the term “wavelength” refers to the peak emission wavelength of the LED. It should be understood that a typical emission spectra of a semiconductor LED is a narrow band of wavelength centered around the peak wavelength.

### SUMMARY

According to an aspect of the present disclosure, a method of forming a light emitting device is provided, which includes the steps of: forming a single crystalline gallium nitride layer on a single crystalline substrate; forming a growth mask layer on the single crystalline gallium nitride layer; forming an array of apertures through the growth mask layer to physically expose portions of a top surface of the single crystalline gallium nitride layer; forming Group III nitride nanostructures containing a nitride of at least one Group IIIA element that includes gallium through the array of apertures on the single crystalline gallium nitride layer; depositing a indium gallium nitride material on the Group III nitride nanostructures until a continuous indium gallium nitride layer that continuously extends over all apertures of the array of apertures is formed; and forming at least one light emitting diode including an indium gallium nitride active region that emits light at a peak wavelength in a range from 615 nm to 750 nm over the continuous indium gallium nitride layer.

According to another aspect of the present disclosure, a light emitting device is provided, which comprises: a continuous indium gallium nitride layer that includes a continuous single crystalline indium gallium nitride material portion, wherein the continuous indium gallium nitride layer has a dislocation density that decreases with distance from a bottom surface of the continuous indium gallium nitride layer and dislocations extend from the bottom surface of the continuous indium gallium nitride layer and terminate within the continuous indium gallium nitride layer; and at least one light emitting diode including an active region that emits light at a peak wavelength in a range from 615 nm to 750 nm and located over the continuous indium gallium nitride layer.

### BRIEF DESCRIPTION OF THE DRAWINGS

FIG. 1A is a vertical cross-sectional view of a first exemplary structure after formation of a single crystalline gallium nitride layer and a growth mask layer including an array of apertures therein according to a first embodiment of the present disclosure.

FIG. 1B is a top-down view of the first exemplary structure of FIG. 1A for the case in which the apertures in the growth mask layer are circular.

FIG. 1C is a top-down view of the first exemplary structure of FIG. 1A for the case in which the apertures in the growth mask layer are hexagonal.

FIG. 1D is a vertical cross-sectional view of the first exemplary structure after formation of pyramidal indium gallium nitride portions as Group III nitride nanostructures through the apertures in the growth mask layer according to the first embodiment of the present disclosure.

FIG. 1E is a vertical cross-sectional view of the first exemplary structure after formation of a continuous indium gallium nitride layer that includes faceted portions according to the first embodiment of the present disclosure.

FIG. 1F is a vertical cross-sectional view of the first exemplary structure after planarization of the top surface of the continuous indium gallium nitride layer according to the first embodiment of the present disclosure.

FIG. 2A is a vertical cross-sectional view of a second exemplary structure after formation of a single crystalline gallium nitride layer and a growth mask layer including an array of apertures therein according to a second embodiment of the present disclosure.

FIG. 2B is a vertical cross-sectional view of the second exemplary structure after formation of pyramidal gallium nitride portions as Group III nitride nanostructures through the apertures in the growth mask layer according to the second embodiment of the present disclosure.

FIG. 2C is a vertical cross-sectional view of the second exemplary structure after formation of a continuous indium gallium nitride layer that includes faceted portions according to the second embodiment of the present disclosure.

FIG. 2D is a vertical cross-sectional view of the second exemplary structure after planarization of the top surface of the continuous indium gallium nitride layer according to the second embodiment of the present disclosure.

FIG. 3A is a vertical cross-sectional view of a third exemplary structure after formation of a single crystalline gallium nitride layer and a growth mask layer including an array of apertures therein according to a third embodiment of the present disclosure.

FIG. 3B is a vertical cross-sectional view of the third exemplary structure after formation of nanowires as Group III nitride nanostructures through the apertures in the growth mask layer according to the third embodiment of the present disclosure.

FIG. 3C is a vertical cross-sectional view of the third exemplary structure after formation of a continuous indium gallium nitride layer that includes faceted portions according to the third embodiment of the present disclosure.

FIG. 3D is a vertical cross-sectional view of the third exemplary structure after planarization of the top surface of the continuous indium gallium nitride layer according to the third embodiment of the present disclosure.

FIG. 4A is a vertical cross-sectional view of a fourth exemplary structure after formation of a dielectric mask layer according to an embodiment of the present disclosure.

FIG. 4B is a vertical cross-sectional view of the fourth exemplary structure after formation of nanowires cores according to an embodiment of the present disclosure.

FIG. 4C is a vertical cross-sectional view of the fourth exemplary structure after formation of active regions and a continuous doped III-V compound material layer according to an embodiment of the present disclosure.

FIG. 4D is a vertical cross-sectional view of the fourth exemplary structure after formation of a transparent conductive oxide layer, a reflector layer, and a dielectric material layer according to an embodiment of the present disclosure.

FIG. 4E is a vertical cross-sectional view of the fourth exemplary structure after formation of an opening through the dielectric material layer, at least one metallic barrier layer, and a solder bump according to an embodiment of the present disclosure.

FIG. 4F is a vertical cross-sectional view of the fourth exemplary structure after optional removal of the substrate, the single crystalline gallium nitride layer, and the growth mask layer by laser ablation of the growth mask layer according to an embodiment of the present disclosure.

FIG. 5A is a vertical cross-sectional view of a fifth exemplary structure after formation of a first conductivity type compound semiconductor layer, an active layer, and a second conductivity type compound semiconductor layer according to an embodiment of the present disclosure.

FIG. 5B is a vertical cross-sectional view of the fifth exemplary structure after formation of a transparent conductive oxide layer, a reflector layer, and a dielectric material layer according to an embodiment of the present disclosure.

FIG. 5C is a vertical cross-sectional view of the fifth exemplary structure after formation of an opening through the dielectric material layer, at least one metallic barrier layer, and a solder bump according to an embodiment of the present disclosure.

FIG. 5D is a vertical cross-sectional view of the fifth exemplary structure after optional removal of the substrate, the single crystalline gallium nitride layer, and the growth mask layer by laser ablation of the growth mask layer according to an embodiment of the present disclosure.

### DETAILED DESCRIPTION

Fabrication of a high external quantum efficiency (EQE) red-light emitting diodes employing indium gallium nitride is challenging. Without wishing to be bound by a particular theory, it is believed that the low EQE for red light emission is due to incorporation of high concentration of indium in a gallium indium nitride active region used to emit red light. However, the high concentration of indium in a gallium indium nitride material induces high lattice strain (e.g., compressive strain) on an underlying gallium nitride buffer layer or substrate. Such high lattice strain induces phase separation of indium gallium nitride into indium nitride portions and gallium nitride portions, thereby reducing efficiency of the red light generation. Embodiments of the present disclosure eliminate or reduce the compressive strain in an indium gallium nitride active regions of the LED by forming an indium gallium nitride template layer having a single crystal surface between the substrate and the LED. The template layer may be formed by using Group III nitride nanostructures, such as gallium nitride or indium gallium nitride nanopyramids or nanowires that protrude perpendicular to the surface of the substrate. As used herein, a nanostructure has at least one dimension, such as a width, of 10 microns or less, such as 1 micron or less.

Furthermore, without wishing to be bound by a particular theory, it is believed that red light EQE from an InGaN active region is lower than shorter wavelength color light EQE because the InGaN active region (e.g., quantum well stack) is grown at lower temperature in order to incorporate additional indium into InGaN to achieve red light emission. It is believed that increasing the lattice constant of the template layer upon which InGaN active region is grown will lead to an increase in indium uptake at a given temperature. Therefore, for example, an InGaN active region emitting red light having a 625 nm peak wavelength may be grown at 20 to 50 C higher temperature when deposited on a larger lattice constant InGaN template layer compared to on a GaN template layer. The higher growth temperature is believed to improve the InGaN active region quality and improves the red light EQE.

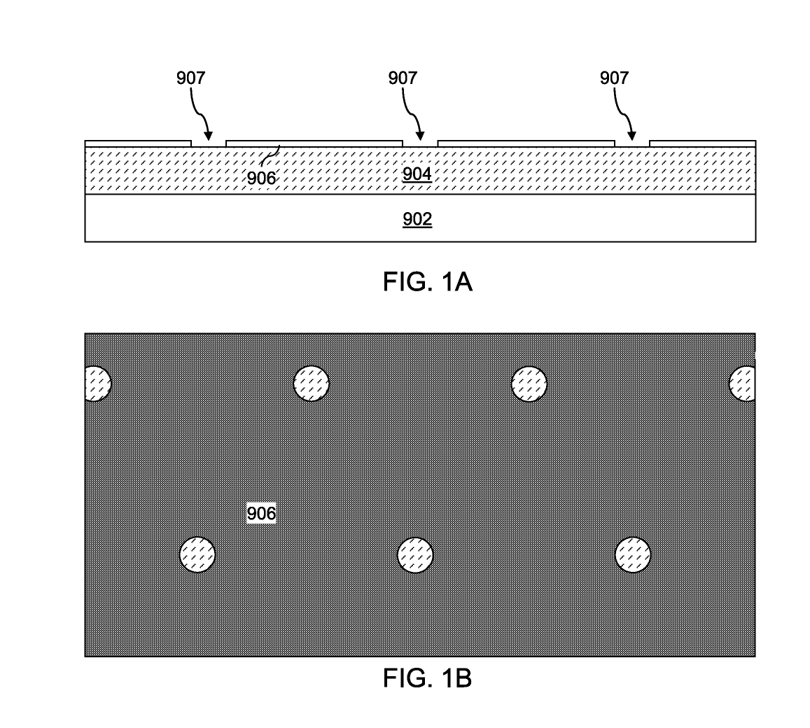

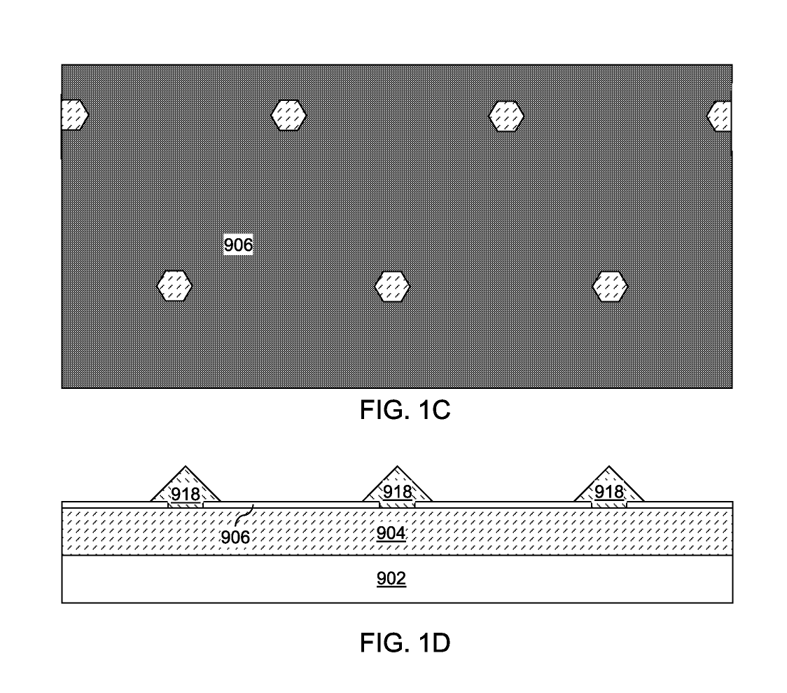

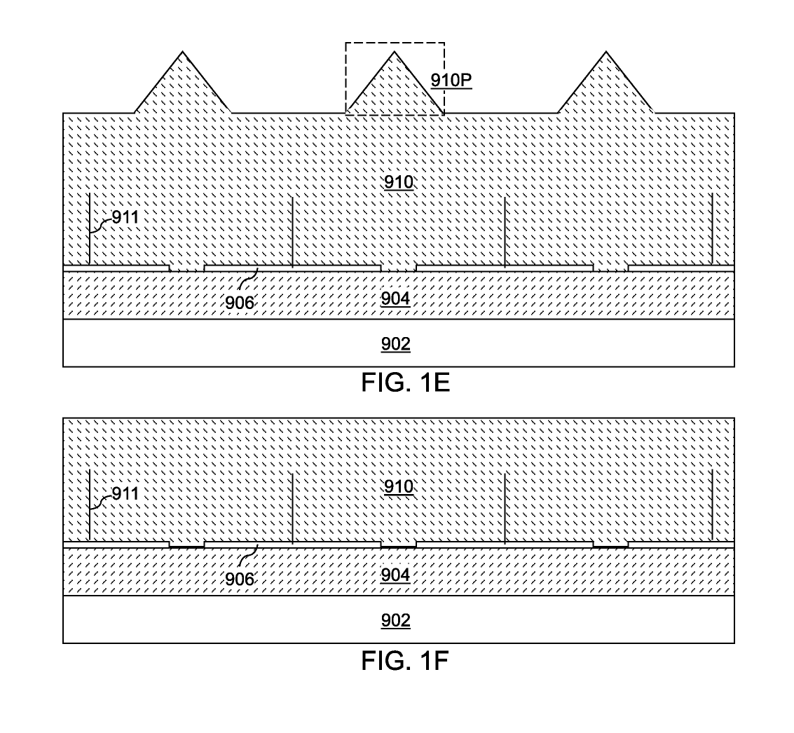

Referring FIGS. 1A-1C, a first exemplary structure is illustrated, which includes a substrate 902, a single crystalline gallium nitride layer 904, and a growth mask layer 906 including apertures 907 therein. FIG. 1A is a vertical cross-sectional view, FIG. 1B is a top-down view for the case in which the apertures 907 in the growth mask layer 906 have circular peripheries, and FIG. 1C is a top-down view for the case in which the apertures 907 in the growth mask layer 906 have hexagonal peripheries.

In one embodiment, the substrate 902 can be a single crystalline substrate on which a III-V compound semiconductor material can be epitaxially deposited. For example, the substrate 902 can be a sapphire (aluminum oxide) layer having a c-plane (0001 plane) as the crystallographic plane of the top surface. A miscut may be present on the top surface of the substrate 902.

The single crystalline gallium nitride layer 904 includes a single crystalline gallium nitride material in epitaxial alignment with the crystalline structure of the substrate 902. The single crystalline gallium nitride layer 904 can be formed, for example, by an epitaxial deposition process such as metal-organic chemical vapor deposition (MOCVD) process. The thickness of the single crystalline gallium nitride layer 904 can be selected such that dislocation defects caused by lattice mismatch between the lattice parameters of the substrate 902 and gallium nitride are healed, and the defect density decreases to a level suitable for device fabrication at the top surface of the single crystalline gallium nitride layer 904. For example, the thickness of the single crystalline gallium nitride layer 904 can be in a range from 1.2 microns to 6 microns, although lesser and greater thicknesses can also be employed. The single crystalline gallium nitride layer 904 may be intrinsic, or may be doped with electrical dopants of a first conductivity type. For example, the single crystalline gallium nitride layer 904 may be n-doped by introduction of silicon as n-type dopants during the epitaxial deposition process.

The growth mask layer 906 includes a material from which III-V compound semiconductor materials do not grow during a selective epitaxy process. For example, the growth mask layer 906 can include a metal, such as titanium, or a dielectric material, such as silicon nitride or silicon oxide. In one embodiment, the growth mask layer 906 can include a silicon nitride layer having a thickness in a range from 3 nm to 100 nm, although lesser and greater thicknesses can also be employed. The growth mask layer 906 can be formed, for example, by deposition of a blanket (unpatterned) dielectric material layer on the top surface of the single crystalline gallium nitride layer 904, application and patterning of a photoresist layer over the blanket dielectric material layer to form an array of openings through the photoresist layer, and an etch process that transfers the pattern of the openings through the photoresist layer into the blanket dielectric material layer, thereby patterning the blanket dielectric material layer into the aperture-containing dielectric material layer 906. The etch process that transfers the pattern of openings in the photoresist layer into the blanket dielectric material layer may be an isotropic etch process or an anisotropic etch process. For example, if the blanket dielectric material layer includes silicon nitride, the etch process can include a wet etch process employing hot phosphoric acid. The photoresist layer can be subsequent removed, for example, by ashing.

The apertures 907 can be provided as an array. In one embodiment, the array of apertures 907 can be a periodic array of apertures 907 having a periodicity along at least one horizontal direction. The array of apertures 907 can be formed through the growth mask layer 906 to physically expose portions of a top surface of the single crystalline gallium nitride layer 904. In one embodiment, the array of apertures 907 can be a two-dimensional periodic array having a periodicity along two different horizontal directions. In an illustrative example, the array of apertures 907 can be provided as a hexagonal array, a rectangular array, or a triangular array (i.e., a deformed hexagonal array in which the two horizontal directions of periodicity have an angle different from 60 degrees therebetween). The apertures 907 may have the same shape, or may have different shapes. The maximum lateral dimension of each aperture 907 (such as a diameter or a separation distance between apexes located at antipodal points) may be in a range from 20 nm to 300 nm, although lesser and greater maximum lateral dimensions may be employed for each aperture 907. The center-to-center distance between each neighboring pair of apertures 907 can be in a range from 500 nm to 20 microns, such as from 1 micron to 10 microns, although lesser and greater center-to-center distances can also be employed.

Referring to FIG. 1D, a selective epitaxy process is performed to form Group III nitride nanostructures that are epitaxially aligned to the single crystalline structure of the single crystalline gallium nitride layer 904 through the apertures 907. The Group III nitride nanostructures can contain a nitride of at least one Group IIIA element that includes gallium (such as gallium nitride or indium gallium nitride). Each of the Group III nitride nanostructures can grow through the array of apertures 907 and directly from the physically exposed surfaces of the single crystalline gallium nitride layer 904 by the selective epitaxy process, while the nitride of at least one Group IIIA element that includes gallium does not grow from the surfaces of the growth mask layer 906.

In one embodiment, the selective epitaxy process deposits indium gallium nitride, and the Group III nitride nanostructures can include pyramidal indium gallium nitride portions 918 (i.e., nanopyramids). In this case, each of the pyramidal indium gallium nitride portions 918 has a respective pyramidal shape that includes a set of angled facets. In one embodiment, the set of angled facets can contact a top surface of the growth mask layer 906. Each facet may have a triangular shape. Edges of the facets on a same pyramidal indium gallium nitride portion 918 can be adjoined at the apex of the pyramidal shape.

In one embodiment, the ratio of the atomic concentration of indium atoms to the sum of the atomic concentration of indium atoms and the atomic concentration of gallium atoms (i.e., an indium to Group III ratio) in the pyramidal indium gallium nitride portions 918 can be in a range from 0.1 to 0.7, such as from 0.3 to 0.6, although lesser and greater ratios can also be employed. For example, the nanopyramids 918 can have the following formula: InₓGa₁₋ₓN, where 0.1≤x≤0.25, such as where 0.1≤x≤0.13. In one embodiment, the pyramidal indium gallium nitride portions 918 may be doped with dopants of the first conductivity type, which can be the same as the conductivity type of the single crystalline gallium nitride layer 904 in case the single crystalline gallium nitride layer 904 is doped. In one embodiment, the pyramidal indium gallium nitride portions 918 can be n-doped.

Because the area of contact between the single crystalline gallium nitride layer 904 and each of the pyramidal indium gallium nitride portions 918 is limited to the area of the respective aperture in the growth mask layer 906, the epitaxial strain at the interfaces between the single crystalline gallium nitride layer 904 and each of the pyramidal indium gallium nitride portions 918 can be at a level that does not induce strain-induced dislocations at a significant density. Thus, each of the pyramidal indium gallium nitride portions 918 can be epitaxially aligned to the single crystalline gallium nitride layer 904.

Formation of pyramidal indium gallium nitride portions 918 through the growth mask layer 906 can occur under process conditions conductive to formation of pyramidal facets, which are described, for example, in U.S. Pat. Nos. 8,669,125; 8,350,251; and 8,350,249 and U.S. Patent Application Publication Nos. 2011/0309382, 2014/01398620, 2014/0117401, 2014/0117307, 2014/0077220, and 2013/0221322, incorporated herein by reference in their entirety.

Referring to FIG. 1E, the selective epitaxial deposition process that formed the pyramidal indium gallium nitride portions 918 at the processing steps of FIG. 1D is extended until the pyramidal indium gallium nitride portions 918 merge to form a continuous indium gallium nitride layer 910. Deposition of the indium gallium nitride material on the Group III nitride nanostructures (i.e., the pyramidal indium gallium nitride portions 918) continues until a continuous indium gallium nitride layer 910 is formed. The continuous indium gallium nitride layer 910 continuously extends over all apertures 907 of the array of apertures 907. Deposition of the indium gallium nitride material continues after pyramidal indium gallium nitride portions 918 meet to increase the thickness of the continuous indium gallium nitride layer 910.

The thickness of the continuous indium gallium nitride layer 910 increases during further growth of the continuous indium gallium nitride layer 910. The various facets of the pyramidal indium gallium nitride portions 918 meet one another approximately midway between each neighboring pair of apertures 907 in the growth mask layer 906 to form dislocations 911. The dislocations 911 may continuously surround each region from which the pyramidal indium gallium nitride portions 918 initiate growth, i.e., may continuously surround the regions of the apertures 907.

The dislocations 911 disappear as the growth of the continuous indium gallium nitride layer 910 continues. Neighboring portions of the deposited indium gallium nitride materials merge to form continuous single crystalline domains, thereby increasing the average size of defect-free single crystalline domains within the continuous indium gallium nitride layer 910. Thus, the continuous indium gallium nitride layer 910 has a dislocation density that decreases with distance from the growth mask layer 906. Dislocations 911 extend from the growth mask layer 906, and terminate within the continuous indium gallium nitride layer 910. The thickness of the continuous indium gallium nitride layer 910, as measured between a horizontal plane including the top surface of the growth mask layer 906 and the most proximal point in the top surface of the continuous indium gallium nitride layer 910, can be in a range from 1.6 microns to 20 microns, such as from 2.4 microns to 10 microns, although lesser and greater thicknesses can also be employed. The continuous indium gallium nitride layer 910 can have the following formula: InₓGa₁₋ₓN, where 0.1≤x≤0.4, such as where 0.1≤x≤0.2. In one embodiment, the continuous indium gallium nitride layer 910 may be doped with dopants of the first conductivity type, which can be the same as the conductivity type of the single crystalline gallium nitride layer 904 in case the single crystalline gallium nitride layer 904 is doped. In one embodiment, the continuous indium gallium nitride layer 910 can be n-doped.

In some embodiments, protruding faceted portions 910P may be present on the top surface of the continuous indium gallium nitride layer 910. The locations of the protruding faceted portions 910P can be directly above the apertures 907 within the growth mask layer 906. In some embodiments, the apex of each protruding faceted portions 910P may overlap with a geometrical center of an underlying aperture 907 in a top-down view.

Referring to FIG. 1F, in case the protruding faceted portions 910P are present on the top surface of the continuous indium gallium nitride layer 910, a planarization process such as chemical mechanical planarization (CMP) can be performed to remove the protruding faceted portions 910P. A planar top surface of the continuous indium gallium nitride layer 910 can be provided. If the protruding faceted portions 910 are not formed, the planarization process may be omitted. The continuous indium gallium nitride layer 910 is single crystalline, has a greater lattice constant than single crystalline gallium nitride material, and is substantially stress-free. Thus, the continuous indium gallium nitride layer 910 can be employed as a template layer for subsequently forming light emitting devices employing a III-V compound material (such as indium gallium nitride active region) having a greater lattice constant than gallium nitride.

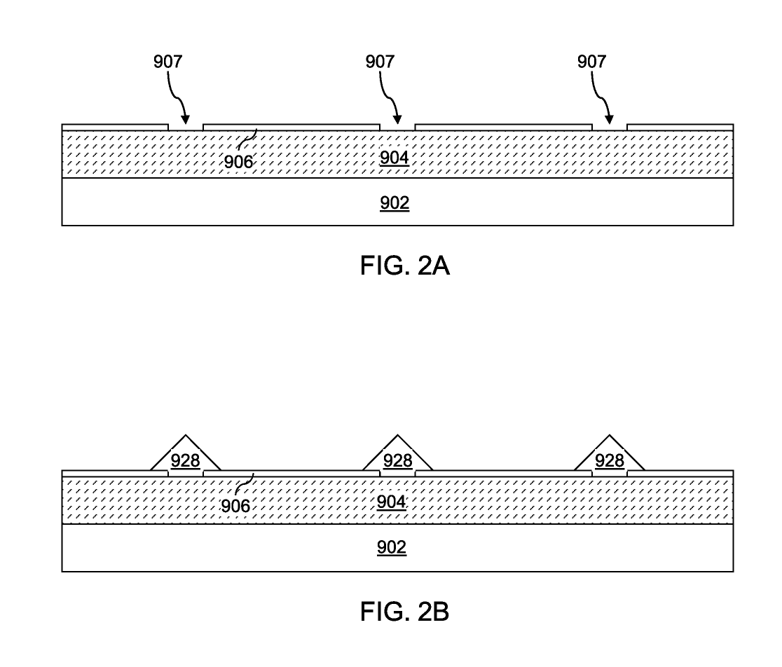

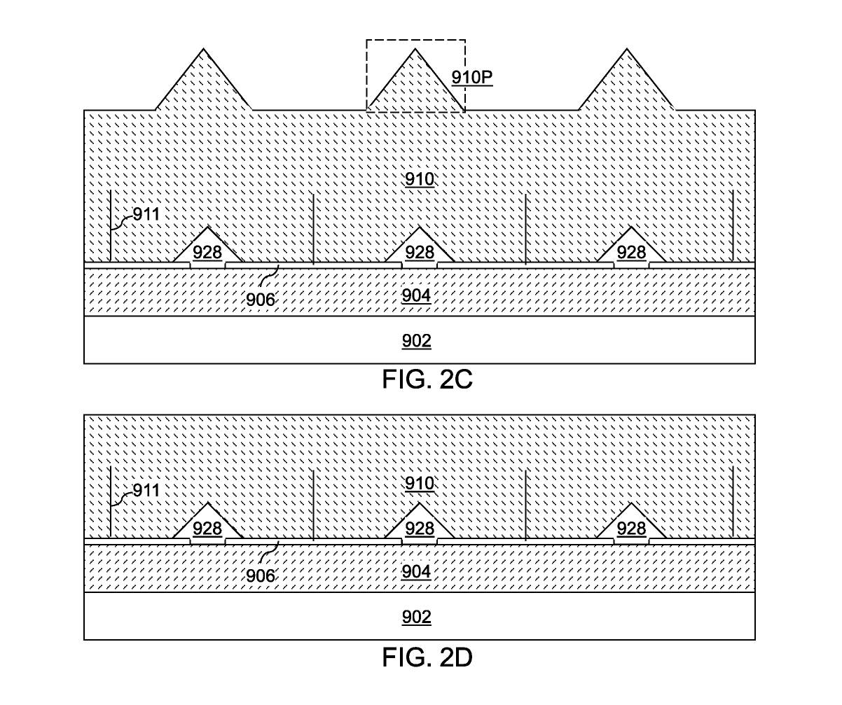

Referring to FIG. 2A, a second exemplary structure according to a second embodiment of the present disclosure is illustrated, in which gallium nitride nanopyramids 928 are used instead of the indium gallium nitride nanopyramids 918. The remaining structure and process is the same as in the first embodiment. The second exemplary structure includes a substrate 902, a single crystalline gallium nitride layer 904, and a growth mask layer 906 including an array of apertures 907 therein. The second exemplary structure of FIG. 2A can be the same as the first exemplary structure illustrated in FIGS. 1A, 1B, and 1C.

Referring to FIG. 2B, a selective epitaxy process is performed to form Group III nitride nanostructures 928 that are epitaxially aligned to the single crystalline structure of the single crystalline gallium nitride layer 904 through the apertures 907.

In this embodiment, the selective epitaxy process deposits indium gallium nitride, and the Group III nitride nanostructures can include pyramidal gallium nitride portions (i.e., GaN nanopyramids) 928. In this case, each of the Group III nitride nanostructures (as embodied as pyramidal gallium nitride portions 928) comprises a gallium nitride material, and has a respective pyramidal shape that includes a set of angled facets. In one embodiment, the set of angled facets can contact a top surface of the growth mask layer 906. Each facet may have a triangular shape. Edges of the facets on a same pyramidal gallium nitride portion 928 can be adjoined at the apex of the pyramidal shape.

In one embodiment, the pyramidal gallium nitride portions 928 may be doped with dopants of the first conductivity type, which can be the same as the conductivity type of the single crystalline gallium nitride layer 904 in case the single crystalline gallium nitride layer 904 is doped. In one embodiment, the pyramidal gallium nitride portions 928 can be n-doped.

Because the single crystalline gallium nitride layer 904 and the pyramidal gallium nitride portions 928 include gallium nitride, the epitaxial strain at the interfaces between the single crystalline gallium nitride layer 904 and each of the pyramidal gallium nitride portions 928 is virtually zero. Thus, each of the pyramidal gallium nitride portions 928 can be epitaxially aligned to the single crystalline gallium nitride layer 904.

Formation of pyramidal gallium nitride portions 928 through the growth mask layer 906 can occur under process conditions conductive to formation of pyramidal facets, which are described, for example, in U.S. Pat. Nos. 8,669,125; 8,350,251; and 8,350,249 and U.S. Patent Application Publication Nos. 2011/0309382, 2014/01398620, 2014/0117401, 2014/0117307, 2014/0077220, and 2013/0221322, incorporated herein by reference in their entirety.

Referring to FIG. 2C, indium gallium nitride material is deposited on the pyramidal gallium nitride portions 928 by another selective epitaxial deposition process. In one embodiment, the ratio of the atomic concentration of indium atoms to the sum of the atomic concentration of indium atoms and the atomic concentration of gallium atoms (i.e., an indium to Group III ratio) in the deposited indium gallium nitride material can be in a range from 0.1 to 0.7, such as from 0.3 to 0.6, although lesser and greater ratios can also be employed. In one embodiment, the deposited indium gallium nitride material may be doped with dopants of the first conductivity type, which can be the same as the conductivity type of the single crystalline gallium nitride layer 904 in case the single crystalline gallium nitride layer 904 is doped. In one embodiment, the deposited indium gallium nitride material can be n-doped.

Each deposited indium gallium nitride material portion is in epitaxial alignment with the underlying pyramidal gallium nitride portion 928. The area of contact between each pyramidal gallium nitride portions 928 and an overlying indium gallium nitride material portion is limited to the surface area of the underlying pyramidal gallium nitride portion 928, which is less than the area of the single crystalline gallium nitride layer 904 by a factor of 10 or more. Thus, the epitaxial strain at the interfaces between the pyramidal gallium nitride portions 928 and the indium gallium nitride material portions can be at a level that does not induce strain-induced dislocations at a significant density. Thus, each of the deposited indium gallium nitride material portions can be epitaxially aligned to the single crystalline gallium nitride layer 904 through the pyramidal gallium nitride portions 928.

Deposition of the indium gallium nitride material by selective epitaxy continues until the deposited indium gallium nitride material portions merge to form a continuous indium gallium nitride layer 910. Thus, deposition of the indium gallium nitride material on the Group III nitride nanostructures (i.e., the pyramidal gallium nitride portions 928) continues until the continuous indium gallium nitride layer 910 is formed. The continuous indium gallium nitride layer 910 continuously extends over all apertures 907 of the array of apertures 907. Deposition of the indium gallium nitride material continues after the indium gallium nitride material portions meet to increase the thickness of the continuous indium gallium nitride layer 910.

The thickness of the continuous indium gallium nitride layer 910 increases during further growth of the continuous indium gallium nitride layer 910. The various facets of the deposited indium gallium nitride portions meet one another approximately midway between each neighboring pair of apertures 907 in the growth mask layer 906 to form dislocations 911. The dislocations 911 may continuously surround pyramidal gallium nitride portions 928, i.e., may continuously surround the regions of the apertures 907.

The dislocations 911 disappear as the growth of the continuous indium gallium nitride layer 910 continues. Neighboring portions of the deposited indium gallium nitride materials merge to form continuous single crystalline domains, thereby increasing the average size of defect-free single crystalline domains within the continuous indium gallium nitride layer 910. Thus, the continuous indium gallium nitride layer 910 has a dislocation density that decreases with distance from the growth mask layer 906. Dislocations 911 extend from the growth mask layer 906, and terminate within the continuous indium gallium nitride layer 910. The thickness of the continuous indium gallium nitride layer 910, as measured between a horizontal plane including the top surface of the growth mask layer 906 and the most proximal point in the top surface of the continuous indium gallium nitride layer 910, can be in a range from 1.6 microns to 20 microns, such as from 2.4 microns to 10 microns, although lesser and greater thicknesses can also be employed.

Referring to FIG. 2D, in case the protruding faceted portions 910P are present on the top surface of the continuous indium gallium nitride layer 910, a planarization process such as chemical mechanical planarization (CMP) can be performed to remove the protruding faceted portions 910P. A planar top surface of the continuous indium gallium nitride layer 910 can be provided. If the protruding faceted portions 910 are not formed, the planarization process may be omitted. The continuous indium gallium nitride layer 910 is single crystalline, has a greater lattice constant than single crystalline gallium nitride material, and is substantially stress-free. The continuous indium gallium nitride layer 910 can have the following formula: InₓGa₁₋ₓN, where 0.1≤x≤0.4, such as where 0.1≤x≤0.2. Thus, the continuous indium gallium nitride layer 910 can be employed as a template layer for subsequently forming light emitting devices employing a III-V compound material (such as indium gallium nitride) having a greater lattice constant than gallium nitride.

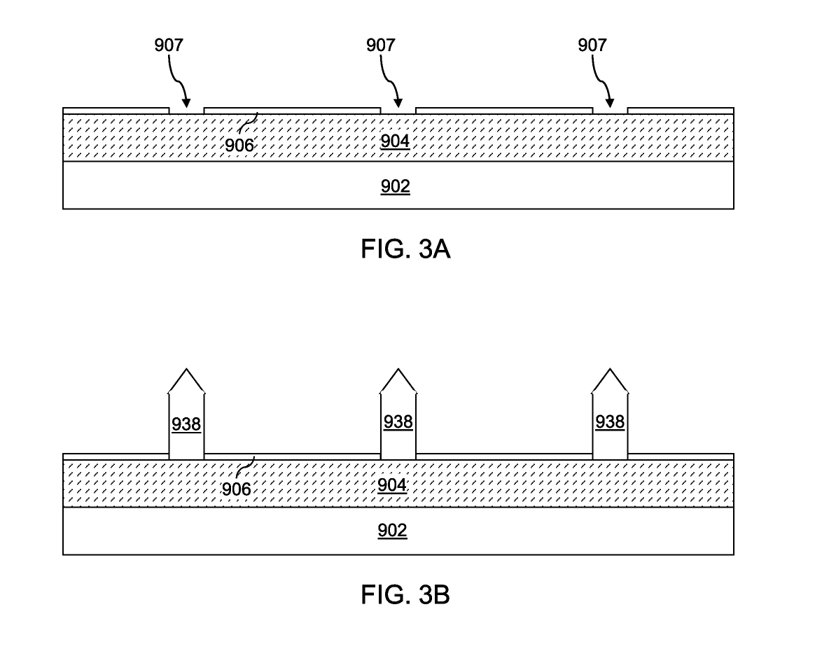

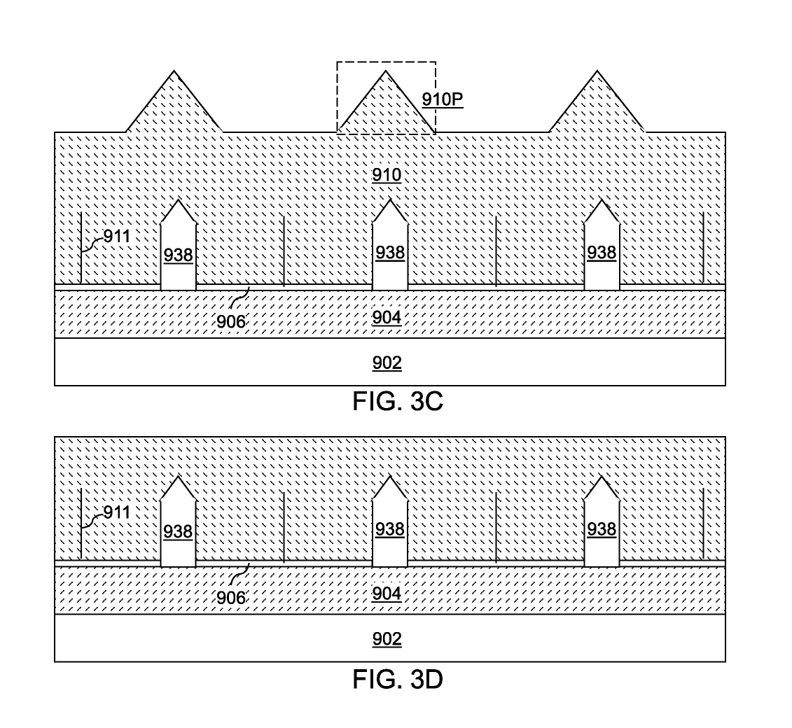

Referring to FIG. 3A, a third exemplary structure according to a third embodiment of the present disclosure is illustrated, in which the Group III nitride nanostructures comprise nanowires 938 instead of nanopyramids (918, 928). Otherwise, the third exemplary structure and the method of the third embodiment are the same as those of the first and second embodiments. The third exemplary structure includes a substrate 902, a single crystalline gallium nitride layer 904, and a growth mask layer 906 including an array of apertures 907 therein. The second exemplary structure of FIG. 3A can be the same as the first exemplary structure illustrated in FIGS. 1A, 1B, and 1C.

Referring to FIG. 3B, a selective epitaxy process is performed to form Group III nitride nanostructures that are epitaxially aligned to the single crystalline structure of the single crystalline gallium nitride layer 904 through the apertures 907. In this embodiment, each of the Group III nitride nanostructures is a respective nanowire 938. Each nanowire 938 includes substantially vertical sidewalls that extend from the top surface of the single crystalline gallium nitride layer 904 through a respective aperture 907 in the growth mask layer 906 to a top periphery that is raised above the horizontal plane including a top surface of the growth mask layer 906. Each nanowire 938 further includes a set of angled facets that are adjoined to the top periphery of the substantially vertical sidewalls.

In one embodiment, the Group III nitride nanostructures, i.e., the nanowires 938, comprise a gallium nitride material. In this case, the epitaxial strain between the nanowires 938 and the single crystalline gallium nitride layer 904 can be negligible.

In another embodiment, the Group III nitride nanostructures, i.e., the nanowires 938, comprise an indium gallium nitride material. The indium gallium nitride material of the nanowires 938 may have the same material composition as, may have a lower atomic concentration of indium than, an indium gallium nitride material to be subsequently deposited.

In one embodiment, the nanowires 938 may be doped with dopants of the first conductivity type, which can be the same as the conductivity type of the single crystalline gallium nitride layer 904 in case the single crystalline gallium nitride layer 904 is doped. In one embodiment, the nanowires 938 can be n-doped.

Formation of nanowires 938 through the growth mask layer 906 can occur under process conditions conductive to formation of pyramidal facets, which are described, for example, in U.S. Pat. Nos. 9,035,278; 8,999,737; 8,937,295; 8,921,141; 8,901,534; 8,669,574; 8,669,125; 8,664,636; 8,350,251; and 8,350,249, incorporated herein by reference in their entirety.

Referring to FIG. 3C, indium gallium nitride material is deposited on the nanowires 938 by another selective epitaxial deposition process. In one embodiment, the ratio of the atomic concentration of indium atoms to the sum of the atomic concentration of indium atoms and the atomic concentration of gallium atoms (i.e., an indium to Group III ratio) in the deposited indium gallium nitride material can be in a range from 0.1 to 0.7, such as from 0.3 to 0.6, although lesser and greater ratios can also be employed (e.g., the nanowires may have the following formula InₓGa₁₋ₓN, where 0.1≤x≤0.25, such as 0.1≤x≤0.13. In one embodiment, the deposited indium gallium nitride material may be doped with dopants of the first conductivity type, which can be the same as the conductivity type of the single crystalline gallium nitride layer 904 in case the single crystalline gallium nitride layer 904 is doped. In one embodiment, the deposited indium gallium nitride material can be n-doped.

Each deposited indium gallium nitride material portion is in epitaxial alignment with the underlying nanowires 938. The area of contact between each nanowire 938 and an overlying indium gallium nitride material portion is limited to the surface area of the underlying nanowires 938, which is less than the area of the single crystalline gallium nitride layer 904 by a factor of 10 or more. Thus, the epitaxial strain at the interfaces between the nanowires 938 and the indium gallium nitride material portions can be at a level that does not induce strain-induced dislocations at a significant density. Thus, each of the deposited indium gallium nitride material portions can be epitaxially aligned to the single crystalline gallium nitride layer 904 through the nanowires 938.

Deposition of the indium gallium nitride material by selective epitaxy continues until the deposited indium gallium nitride material portions merge to form a continuous indium gallium nitride layer 910. Thus, deposition of the indium gallium nitride material on the Group III nitride nanostructures (i.e., the nanowires 938) continues until the continuous indium gallium nitride layer 910 is formed. The continuous indium gallium nitride layer 910 continuously extends over all apertures 907 of the array of apertures 907. Deposition of the indium gallium nitride material continues after the indium gallium nitride material portions meet to increase the thickness of the continuous indium gallium nitride layer 910.

The thickness of the continuous indium gallium nitride layer 910 increases during further growth of the continuous indium gallium nitride layer 910. The various facets of the deposited indium gallium nitride portions meet one another approximately midway between each neighboring pair of apertures 907 in the growth mask layer 906 to form dislocations 911. The dislocations 911 may continuously surround nanowires 938, i.e., may continuously surround the regions of the apertures 907.

The dislocations 911 disappear as the growth of the continuous indium gallium nitride layer 910 continues. Neighboring portions of the deposited indium gallium nitride materials merge to form continuous single crystalline domains, thereby increasing the average size of defect-free single crystalline domains within the continuous indium gallium nitride layer 910. Thus, the continuous indium gallium nitride layer 910 has a dislocation density that decreases with distance from the growth mask layer 906. Dislocations 911 extend from the growth mask layer 906, and terminate within the continuous indium gallium nitride layer 910. The thickness of the continuous indium gallium nitride layer 910, as measured between a horizontal plane including the top surface of the growth mask layer 906 and the most proximal point in the top surface of the continuous indium gallium nitride layer 910, can be in a range from 1.6 microns to 20 microns, such as from 2.4 microns to 10 microns, although lesser and greater thicknesses can also be employed.

As shown in FIG. 3D, if the protruding faceted portions 910P are present on the top surface of the continuous indium gallium nitride layer 910, then they are removed by planarization, as described above. The locations of the protruding faceted portions 910P can be directly above the apertures 907 within the growth mask layer 906. In some embodiments, the apex of each protruding faceted portions 910P may overlap with a geometrical center of an underlying aperture 907 in a top-down view.

In case the nanowires 938 includes an indium gallium nitride material, the indium gallium nitride material of the nanowires 938 may have the same material composition as an upper portion of the continuous indium gallium nitride layer, or has a lower atomic concentration of indium than, the upper portion of the continuous indium gallium nitride layer 910.

The continuous indium gallium nitride layer 910 is single crystalline, has a greater lattice constant than single crystalline gallium nitride material, and is substantially stress-free. The continuous indium gallium nitride layer 910 can have the following formula: InₓGa₁₋ₓN, where 0.1≤x≤0.4, such as where 0.1≤x≤0.2. Thus, the continuous indium gallium nitride layer 910 can be employed as a template layer for subsequently forming light emitting devices employing a III-V compound material (such as indium gallium nitride) having a greater lattice constant than gallium nitride.

Each of the exemplary structures illustrated in FIGS. 1F, 2D, and 3D can be employed to form at least one light emitting diode on the top surface of the continuous indium gallium nitride layer 910, which is a single crystalline III-V compound semiconductor material layer having a larger lattice constant than the lattice constant of the single crystalline gallium nitride layer 904. The at least one light emitting diode can include an indium gallium nitride active region that emits light at a peak wavelength in a range from 615 nm to 750 nm, such as 615 nm to 650 nm (i.e., red light).

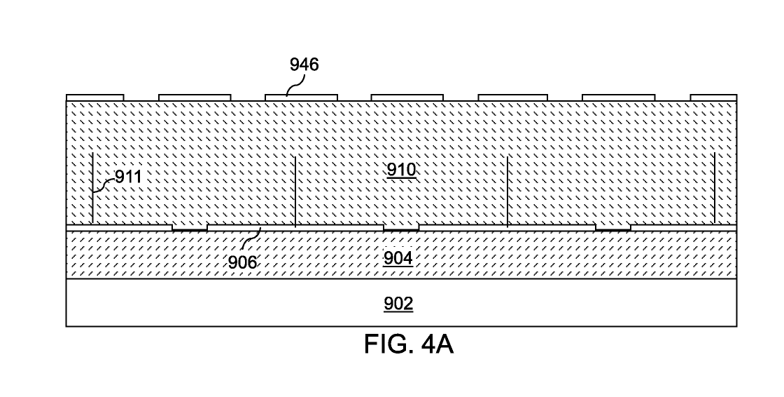

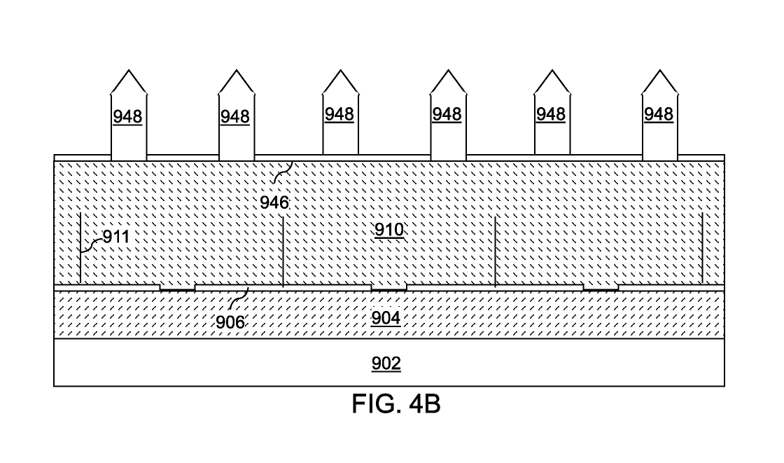

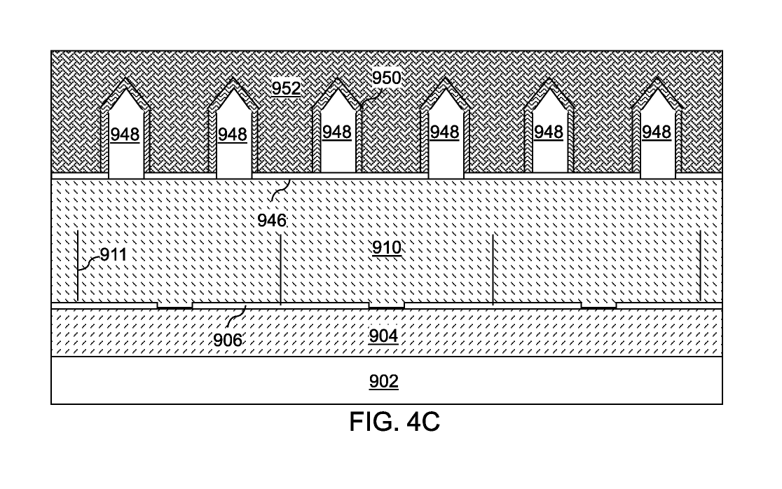

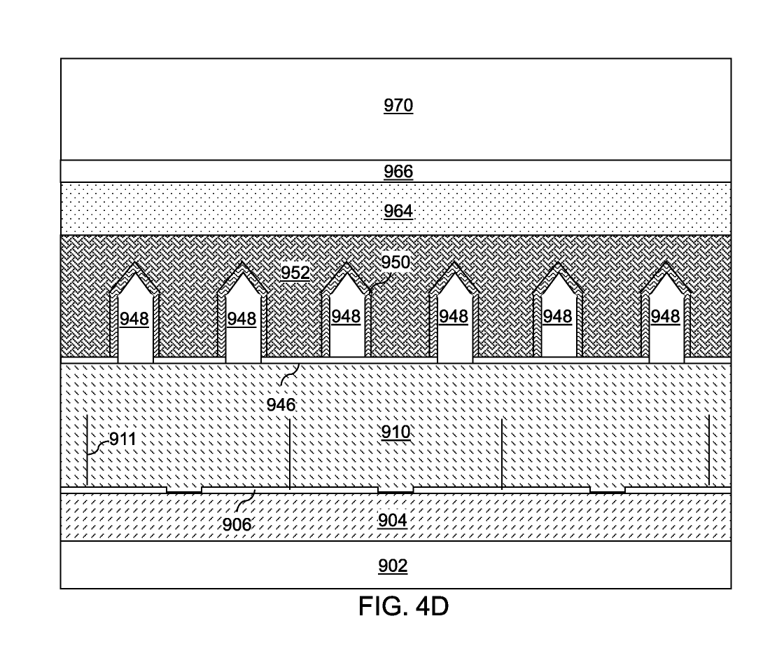

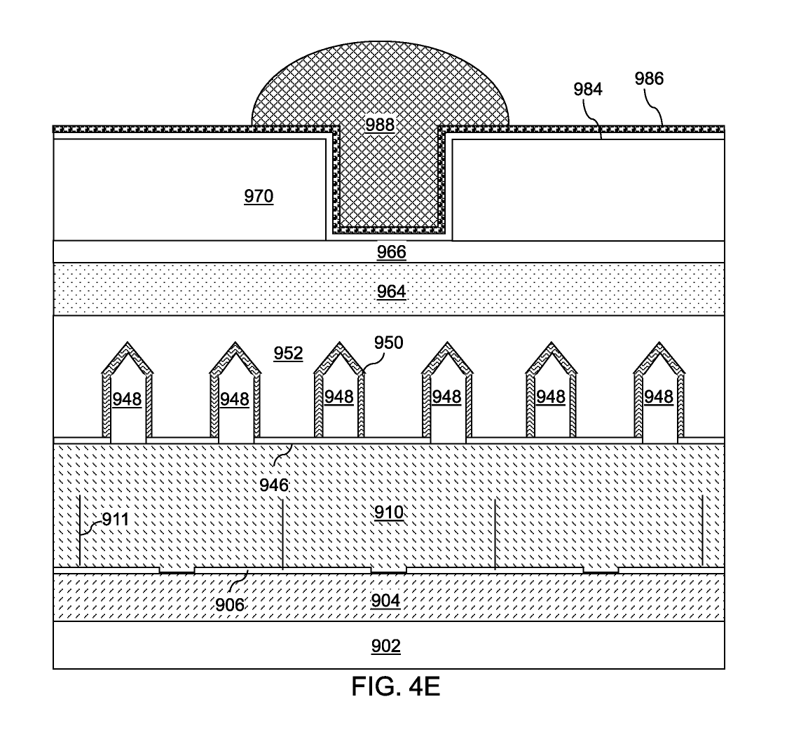

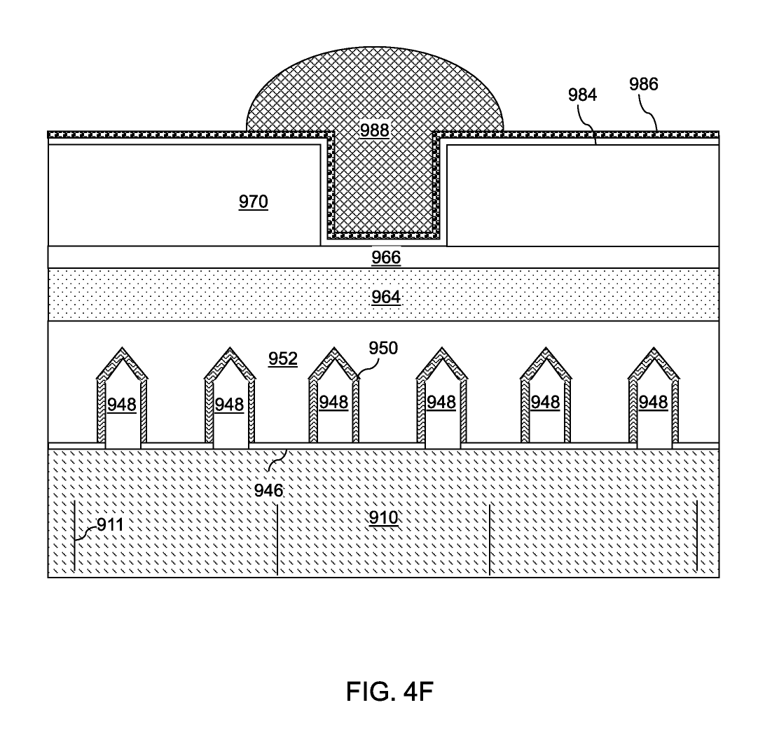

Referring to FIG. 4A, a fourth exemplary structure is shown, which can be formed on any of the exemplary structures illustrated in FIGS. 1F, 2D, and 3D. A patterned mask layer 946 can be formed on the top surface of the continuous indium gallium nitride layer 910. The patterned mask layer 946 can be formed, for example, by depositing a metal layer (e.g., titanium) or dielectric material layer and patterning the layer to form apertures therein. For example, a dielectric material layer, such as silicon nitride layer, a silicon oxide layer, or a dielectric metal oxide layer (such as an aluminum oxide layer) can be formed on the top surface of the substrate 20. In one embodiment, the dielectric material layer can include a silicon nitride layer. The thickness of the dielectric material layer can be in a range from 3 nm to 100 nm, although lesser and greater thicknesses can also be employed.

A photoresist layer (not shown) can be applied over the top surface of the dielectric material layer, and can be lithographically patterned to form apertures therethrough by lithographic exposure and development. In one embodiment, the apertures in the photoresist layer can be formed as a two-dimensional periodic array. The size and shape of each aperture can be selected to optimize the shape and size of nanowires to be subsequently formed. The pattern of the apertures in the photoresist layer can be transferred through the dielectric material layer to form the patterned mask layer 946. The photoresist layer can be subsequently removed, for example, by ashing.

The patterned mask layer 946 includes openings, which may, or may not, be arranged as a two-dimensional periodic array. The shape of each opening may be circular, elliptical, or polygonal (such as hexagonal). The maximum lateral dimension of each openings in the patterned mask layer 946 can be in a range from 10 nm to 1,000 nm, such as from 30 nm to 300 nm, although lesser and greater maximum lateral dimensions can also be employed. A portion of the top surface the indium gallium nitride layer 910 is physically exposed underneath each opening through the patterned mask layer 946.

While a region of the exemplary structure is illustrated herein, it is understood that the exemplary structure can laterally extend along two independent horizontal directions as a two-dimensional array. Thus, multiple instances of the illustrated structures in the drawings can be formed in the exemplary structure, which is typically the case during commercial production of the devices of the present disclosure.

Referring to FIG. 4B, an array of nanowire cores 948 is grown through the openings in the patterned mask layer 946. Each nanowires core 948 includes a doped gallium nitride or indium gallium nitride material having a doping of the first conductivity type, i.e., the conductivity type of doping of the continuous indium gallium nitride layer 910. In one embodiment, the first conductivity type can be n-type, and each nanowires core 948 includes an n-doped indium gallium nitride. In one embodiment, the nanowire cores 948 can have the same, or substantially the same, indium to Group III ratio (i.e., the ratio of the atomic concentration of indium atoms to the sum of the atomic concentration of indium atoms and the atomic concentration of the gallium atoms) as the continuous indium gallium nitride layer 910. In this case, the epitaxial strain between the nanowire cores 948 and the continuous indium gallium nitride layer 910 can be zero or substantially zero.

Each of the nanowires cores 948 can be formed with a set of substantially vertical sidewalls and a tip portion having angled facets, i.e., facets that are not horizontal and not vertical. The nanowires cores 948 can be grown, for example, by selective epitaxial growth of an n-doped compound semiconductor material. The process parameters of the selective epitaxial growth process can be selected such that an n-doped compound semiconductor material grows upward with substantially vertical sidewalls and angled facets from each opening through the patterned mask layer 946. Methods for growing the nanowires cores 948 through the openings in the patterned mask layer 946 with substantially vertical sidewalls and faceted tip portion are described, for example, in U.S. Pat. No. 8,664,636 to Konsek et al., U.S. Pat. No. 8,669,574 to Konsek et al., and U.S. Pat. No. 9,287,443 to Konsek et al., each of which is assigned to Glo AB. The height of the nanowires cores 948 can be in a range from 2 microns to 40 microns, although lesser and greater heights can also be employed.

Referring to FIG. 4C, an active shell 950 is formed on each nanowires core 948. The active shell 950 includes at least one semiconductor material that emits light upon application of a suitable electrical bias. For example, each active shell 950 can include a multi-quantum well (MQW) structure that emits red light upon application of an electrical bias thereacross. For example, each active shell 950 can include a multi-quantum well including multiple repetitions of a combination of a light emitting indium gallium nitride layer having a first thickness (which may be in a range from 1 nm to 10 nm) and barrier layers which have a wider band gap than the indium gallium nitride layer. The barrier layers may comprise gallium nitride, aluminum gallium nitride, indium aluminum gallium nitride or indium gallium nitride having less indium than the light emitting indium gallium nitride layer. The set of all layers within an active shell 950 is herein referred to as an active layer. For example, the light emitting (i.e., quantum well) gallium nitride layer may have the following formula: InₓGa₁₋ₓN, where 0.4≤x≤0.6, such as where 0.45≤x≤0.55 (i.e., which contains a higher indium concentration than the continuous indium gallium nitride layer 910 and the indium gallium nitride nanopyramids 918 or nanowires 938).

A selective epitaxy process can be employed to grow the active shells 950. The process parameters of the selective epitaxy process can be selected such that the active shells 950 are grown as conformal structures having a same thickness throughout. In another embodiment, the active shells 950 can be grown as a pseudo-conformal structure in which the vertical portions have the same thickness throughout, and faceted portions over the tips of the nanowires cores 948 have thicknesses that differ from the thickness of the vertical portions. Methods for growing the active shells 950 on the nanowires cores 948 are described, for example, in U.S. Pat. No. 8,664,636 to Konsek et al., U.S. Pat. No. 8,669,574 to Konsek et al., and U.S. Pat. No. 9,287,443 to Konsek et al., each of which is assigned to Glo AB. The thickness of the vertical portions of the active shells 950 can be selected such that the active shells 950 do not merge among one another. The thickness of the vertical portions of the active shells 950 can be in a range from 20 nm to 1 micron, although lesser and greater thicknesses can also be employed.

Each set of a nanowires core 948 and an active shell 950 that contacts, surrounds, and overlies the nanowires core 948 constitutes a nanowire (948, 950). In one embodiment, the set of all nanowires (948, 950) formed on the substrate 20 can include a group of nanowires (948, 950) that remain in a final device structure, and additional nanowires (948, 950) that are located outside the area of the group of nanowires (948, 950) and are subsequently removed, and thus, are not incorporated into the final device structure. All nanowires (948, 950), including the array of nanowires (948, 950) and the additional nanowires (948, 950) can be grown through openings in the patterned mask layer 946 employing at least one selective epitaxy process, which can be at least two selective epitaxy processes including a first selective epitaxy process that forms the nanowires cores 948 and at least one second selective epitaxy process that forms the active shells 950.

An array of combinations of a nanowire core 948 and a shell 950 is formed through the openings in the dielectric mask layer 946. Each nanowire core 948 includes a III-V compound material having a doping of the first conductivity type, and each shell 950 laterally surrounds a respective nanowire core 948 and includes a respective active region that emits light at the peak wavelength upon application of an electrical bias thereacross. In one embodiment, the active region within each shell 950 can be configured to emit light at a peak wavelength in a range from 615 nm to 750 nm, such as 615 nm to 650 nm, and located on a top surface of the continuous indium gallium nitride layer.

The nanowires (948, 950) can be formed as a two-dimensional array having periodicity along two independent directions. Each nanowire (948, 950) within the array extends vertically from the top surface of the doped compound semiconductor layer 26. Each nanowire (948, 950) within the array includes a nanowire core 948 having a doping of the first conductivity type and an active shell 950 including an active layer emitting light upon application of electrical bias therethrough.

Referring to FIG. 4C, a continuous doped III-V compound material layer 952 is formed on the sidewalls and faceted outer surfaces of the nanowires (948, 950). The continuous doped III-V compound material layer 952 includes a doped semiconductor material having a doping of a second conductivity type, which is the opposite of the first conductivity type. For example, if the first conductivity type is n-type, the second conductivity type is p-type. If the first conductivity type is p-type, the second conductivity type is n-type.

The compound semiconductor material of the continuous doped III-V compound material layer 952 can be selected to optimize efficiency of the active shells 950 for a given composition of the first conductivity type doped compound semiconductor material of the nanowires cores 948. In one embodiment, the nanowires cores 948 can include n-doped gallium nitride or indium gallium nitride, and the continuous doped III-V compound material layer 952 can include p-doped gallium nitride, indium gallium nitride or aluminum gallium nitride.

In one embodiment, the thickness of the deposited compound semiconductor material of the continuous doped III-V compound material layer 952 can be selected so that the volumes between neighboring pairs of nanowires (948, 950) are filled with vertical portions of the continuous doped III-V compound material layer 952. The continuous doped III-V compound material layer 952 includes a horizontally extending portion that continuously extends horizontally and overlies the array of nanowires (948, 950) and vertical portions that are located between neighboring pairs of nanowires (948, 950). The horizontally extending portion of the continuous doped III-V compound material layer 952 contacts faceted surfaces of the nanowires (948, 950). Each vertical portion of the continuous doped III-V compound material layer 952 can contact a portion of the top surface of the patterned mask layer 946 and can be adjoined to the horizontally extending portion of the continuous doped III-V compound material layer 952. The thickness of the horizontally extending portion of the continuous doped III-V compound material layer 952 (as measured along the vertical direction) can be in a range from 100 nm to 2 microns, such as from 200 nm to 1 micron, although lesser and greater thicknesses can also be employed. Referring to FIG. 4D, a top electrode is formed continuous doped III-V compound material layer 952. The top electrode may comprise any suitable electrically conductive material, such as an optional transparent conductive oxide layer 954 which can be deposited over the horizontally extending portion of the continuous doped III-V compound material layer 952. In case light emitted from the active layers of the shells 950 is directed downward by a reflector layer, the transparent conductive oxide layer 954 is herein referred to a backside transparent conductive oxide layer 954. The transparent conductive oxide layer 954 includes a transparent conductive oxide material such as indium tin oxide or aluminum doped zinc oxide. The transparent conductive oxide layer 954 can be deposited as a continuous material layer that extends across the entire area of the continuous doped III-V compound material layer 952, i.e., across the entire area of the array of nanowires (948, 950). The thickness of the transparent conductive oxide layer 954 can be in a range from 100 nm to 2 microns, such as from 200 nm to 1 micron, although lesser and greater thicknesses can also be employed.

Optionally, a reflector material can be deposited to form a reflector layer 966 that continuously extends over the transparent conductive oxide layer 954 and the array of nanowires (948, 950). The reflector layer 966 is electrically shorted to the continuous doped III-V compound material layer 952 through the transparent conductive oxide layer 954. In one embodiment, the reflector layer 966 includes at least one material selected from silver, aluminum, copper, and gold. In one embodiment, the reflector material can be deposited by a directional deposition method such as physical vapor deposition (sputtering) or vacuum evaporation. The reflector layer 966 can be employed to reflect light emitted from the active shells 950 downward.

A dielectric material is deposited over the reflector layer 966 and to form a dielectric material layer 970. The dielectric material layer 970 is formed over, and around, the reflector layer 966. The dielectric material of the dielectric material layer 970 can be a self-planarizing dielectric material such as spin-on glass (SOG) that can be formed by spin coating. Alternatively, the dielectric material of the dielectric material layer 970 can be a non-self-planarizing material. In this case, the dielectric material layer 970 may, or may not, be subsequently planarized. If the dielectric material layer 970 is planarized, a chemical mechanical planarization (CMP) process can be employed. In one embodiment, the dielectric material of the dielectric material layer 970 can include doped silicate glass or undoped silicate glass. The thickness of the dielectric material layer 970 can be in a range from 100 nm to 4 microns, such as from 200 nm to 2 microns, although lesser and greater thicknesses can also be employed.

Referring to FIG. 4E, openings can be formed through the dielectric material layer 970 to a top surface of the reflector layer 966. For example, a photoresist layer (not shown) can be applied over the dielectric material layer 970, and can be lithographically patterned to form openings therein. The pattern of the openings in the photoresist layer can be transferred through the dielectric material layer 970 by an anisotropic etch or an isotropic etch to form the openings in the dielectric material layer 970. For example, a wet etch employing hydrofluoric acid or a reactive ion etch employing a fluorocarbon etchant can be employed to form the opening through the dielectric material layer 970. In one embodiment, one opening through the dielectric material layer 970 can be formed per one die area, i.e., per each set of nanowires (948, 950) to be employed for a single red-light emitting subpixel.

At least one metallic barrier layer (984, 986) can be formed as at least one continuous material layer over the top surface of the dielectric material layer 970 and in the opening through the dielectric material layer 970. The at least one metallic barrier layer (984, 986) can be formed directly on the reflector layer 966. The at least one metallic barrier layer (984, 986) extends vertically through the openings through the dielectric material layer 970, and is electrically shorted to the reflector layer 966, the transparent conductive oxide layer 954, and the continuous doped III-V compound material layer 952.

The at least one metallic barrier layer (984, 986) includes metallic material layers that can be employed for under-bump metallurgy (UBM), i.e., a set of metal layers provide between a solder bump and a die. In one embodiment, the at least one metallic barrier layer (984, 986) can include a diffusion barrier layer 984 and an adhesion promoter layer 986. Exemplary materials that can be employed for the diffusion barrier layer 984 include titanium and tantalum. Exemplary materials that can be employed for the adhesion promoter layer 986 include a stack, from bottom to top, of copper and nickel, tungsten, platinum, and a stack of tungsten and platinum. Any other under-bump metallurgy known in the art can also be employed. The at least one metallic barrier layer (984, 986) includes a horizontal portion that overlies the dielectric material layer 970 and a vertically protruding portion that adjoins an inner periphery of the horizontal portion and contacting sidewalls of the dielectric material layer 970 and the reflector layer 966.

A solder bump 988 can be formed in the cavity within the opening in the dielectric material layer 970 and over a portion of the top surface of the at least one metallic barrier layer (984, 986) located around the opening in the dielectric material layer 970. The solder bump 988 includes a solder material, which can include tin, and optionally includes silver, copper, bismuth, indium, zinc, and/or antimony. The upper portion of the solder bump 988 located above the horizontal plane including the top surface of the at least one metallic barrier layer (984, 986) can have a shape of a predominant portion of a sphere. It is understood that shape of the solder bump 988 as illustrated is only schematic, and may not represent a true shape of a solder bump 988. The lower portion of the solder bump 988 fills the opening in the dielectric material layer 970. If the solder bump 988 has a shape of a predominant portion of a sphere, the diameter of the sphere can be in a range from 15 microns to 60 microns, although lesser and greater diameters can also be employed. The lower portion of the solder bump 988 can be formed directly on a sidewall of the at least one metallic barrier layer (984, 986) within the opening through the dielectric material layer 970 and directly on a top surface of a recessed portion of the at least one metallic barrier layer (984, 986). The solder bump 988 is electrically shorted to the reflector layer 966, the transparent conductive oxide layer 954, and the continuous doped III-V compound material layer 952.

Referring to FIG. 4F, the substrate 902, the single crystalline gallium nitride layer 904, and the growth mask layer 906 can be optionally removed. For example, laser beam can pass through the substrate 902 (including a material such as sapphire) and ablate the bottom surface region of the single crystalline gallium nitride layer 904, thereby detaching the substrate 902 from remaining portions of the single crystalline gallium nitride layer 904 and the structures thereupon. Chemical mechanical planarization can be employed to remove the single crystalline gallium nitride layer 904, and the growth mask layer 906 to physically expose the bottom surface of the continuous indium gallium nitride layer 910. A temporary masking material (not shown) such as a polymer, silicon nitride, silicon oxide, or a combination thereof, may be employed to protect the solder bump during the planarization process. Alternatively, an etch process, such as a wet etch process or a reactive ion etch process, may be employed to remove the single crystalline gallium nitride layer 904, and the growth mask layer 906 to physically expose the bottom surface of the continuous indium gallium nitride layer 910. The physically exposed surface of the continuous indium gallium nitride layer 910 is herein referred to as a distal surface, i.e., a surface that is distal from the active region 950. The fourth exemplary structure can be subsequently singulated and/or transferred to form a display device including red-light emitting diodes. In subsequent fabrication processes, an electrode for each light emitting diode can be formed on a respective solder bump 988, and another electrode for each light emitting diode can be formed on a respective portion of the distal surface of the continuous indium gallium nitride layer 910.

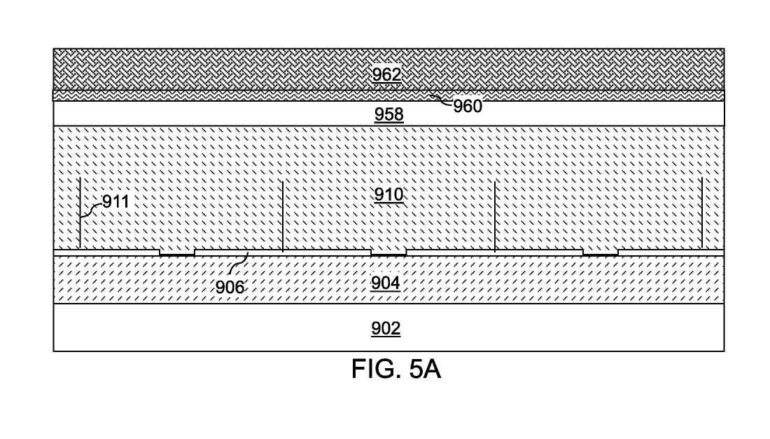

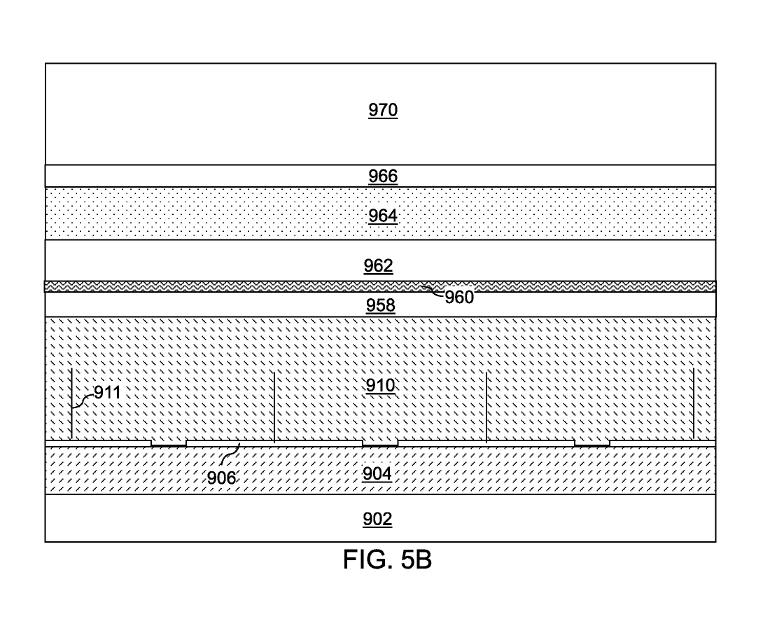

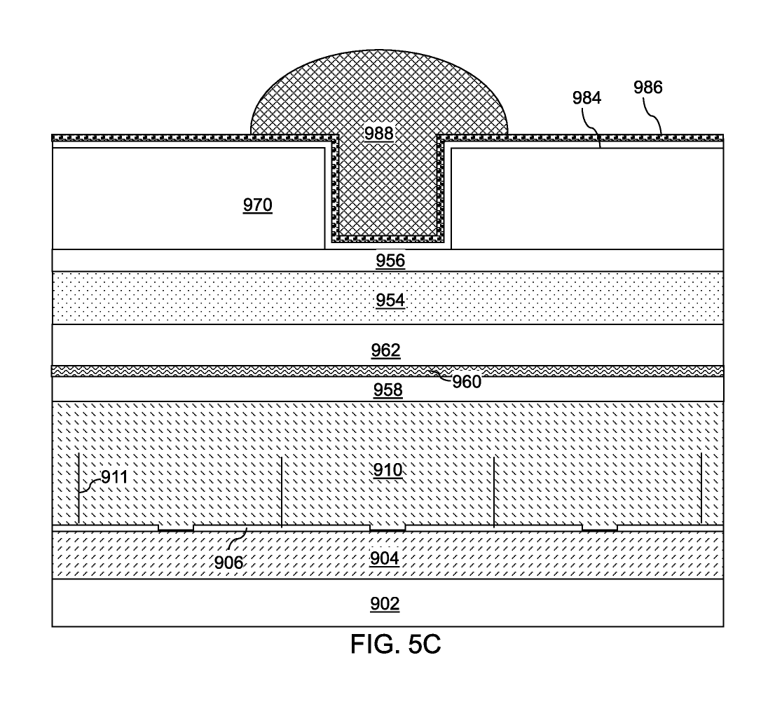

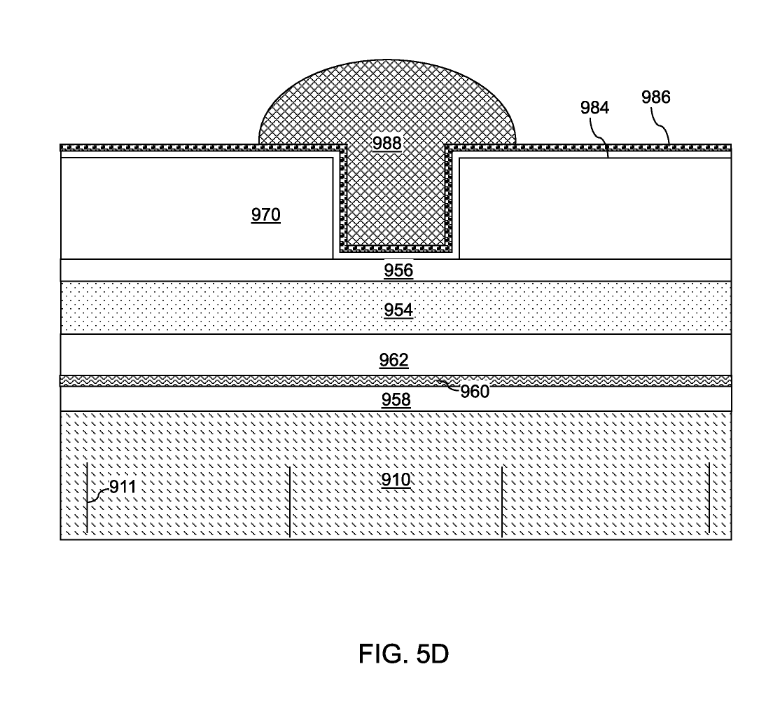

Referring to FIG. 5A, a fifth exemplary structure is shown, which can be formed on any of the exemplary structures illustrated in FIGS. 1F, 2D, and 3D. A first conductivity type compound semiconductor layer (i.e., a planar/bulk layer) 958, an active layer (i.e., a planar layer) 960, and a second conductivity type compound semiconductor layer (i.e., a planar/bulk layer) 962 can be sequentially deposited by a series of epitaxy processes. Each of the epitaxy processes may, or may not, be selective. A planar red-light emitting diode structure is formed by the combination of the first conductivity type compound semiconductor layer 958, the active layer 960, and the second conductivity type compound semiconductor layer 962.

Specifically, one of the first conductivity type compound semiconductor layer 958 and the second conductivity type compound semiconductor layer 962 can be a planar n-doped III-V compound semiconductor material layer located over the continuous indium gallium nitride layer 910. The other of the first conductivity type compound semiconductor layer 958 and the second conductivity type compound semiconductor layer 962 can be a planar p-doped III-V compound semiconductor material layer located over the continuous indium gallium nitride layer 910. The active layer 960 includes an active region located between the planar n-doped III-V compound semiconductor material layer and the planar p-doped III-V compound semiconductor material layer. The active layer 960 emits light at the peak wavelength of 615 nm to 750 nm, such as 615 nm to 650 nm, upon application of an electrical bias thereacross.

Referring to FIG. 5B, the processing steps of FIG. 4D can be performed to form a transparent conductive oxide layer 964, a reflector layer 966, and a dielectric material layer 970.

Referring to FIG. 5C, the processing steps of FIG. 4E can be performed to form an openings through the dielectric material layer 970, at least one metallic barrier layer (984, 986), and solder bump 988.

Referring to FIG. 5D, the processing steps of FIG. 4F can be performed to optionally remove the substrate 902, the single crystalline gallium nitride layer 904, and the growth mask layer 906. The physically exposed surface of the continuous indium gallium nitride layer 910 is herein referred to as a distal surface, i.e., a surface that is distal from the active region 960. The fifth exemplary structure can be subsequently singulated and/or transferred to form a display device including red-light emitting diodes. In subsequent fabrication processes, an electrode for each light emitting diode can be formed on a respective solder bump 988, and another electrode for each light emitting diode can be formed on a respective portion of the distal surface of the continuous indium gallium nitride layer 910.

Each of the fourth and fifth exemplary structures can include a light emitting device. The light emitting device can include: a continuous indium gallium nitride layer 910 that includes a continuous single crystalline indium gallium nitride material portion, wherein the continuous indium gallium nitride layer has a dislocation density that decreases with distance from a bottom surface of the continuous indium gallium nitride layer 910 and dislocations extend from the bottom surface of the continuous indium gallium nitride layer 910 and terminate within the continuous indium gallium nitride layer 910; and at least one light emitting diode including an active region (950 or 960) that emits light at a peak wavelength in a range from 615 nm to 750 nm and located over the continuous indium gallium nitride layer.

The continuous indium gallium nitride layer 910 is a planar template having a surface morphology and dislocation density comparable to planar GaN templates, but having a larger in-plane lattice constant than GaN templates. In one embodiment, the continuous indium gallium nitride layer 910 can have a top surface roughness, measured by AFM on 10×10 micron area, in five locations on wafer (center, midpoint of radius, edge—5mm) of <0.5 nm rms, such as 0.1 to 0.4 nm rms. The continuous indium gallium nitride layer 910 may have an in-plane lattice constant (i.e. 100 or 010 plane spacing)>3.21 Å, such as 3.22 Å to 3.3 Å at same 5 locations on the wafer. The continuous indium gallium nitride layer 910 may have atomic step edges observable by AFM and a dislocation density <1×10⁹ cm⁻², such as 0.1 to 0.9×10⁹cm⁻².

In one embodiment, the light emitting device can further comprise Group III nitride nanostructures (918, 928, 938) containing a nitride of at least one Group IIIA element that includes gallium (e.g., GaN or InGaN), and is located between an upper portion of the continuous indium gallium nitride layer 910 and the bottom surface of the continuous indium gallium nitride layer 910.

In one embodiment, each of the Group III nitride nanostructures (918, 938) comprises an indium gallium nitride material having a different composition than an indium gallium nitride material in the upper portion of the continuous indium gallium nitride layer 910 and different composition than an indium gallium nitride material of the active region (950, 960). For example, each of the Group III nitride nanostructures (918, 938) has the lowest indium content, the continuous indium gallium nitride layer 910 has an intermediate indium content and the active region (950, 960) has the highest indium content.

In one embodiment, each of the Group III nitride nanostructures 928 comprises a gallium nitride material which has a respective pyramidal shape (i.e., GaN nanopyramid) that includes a set of angled facets.

In some embodiments, each of the Group III nitride nanostructures 938 is nanowire that includes substantially vertical sidewalls that extend from the bottom surface of the continuous indium gallium nitride layer 910 to a top periphery that is raised above bottom surface of the continuous indium gallium nitride layer 910; and a set of angled facets that are adjoined to the top periphery of the substantially vertical sidewalls. In one embodiment, the Group III nitride nanostructures 938 comprise an indium gallium nitride material, and the indium gallium nitride material has a lower atomic concentration of indium than the upper portion of the continuous indium gallium nitride layer 910. In one embodiment, the Group III nitride nanostructures 938 comprise a gallium nitride material.

In one embodiment shown in FIG. 4F, the at least one light emitting diode comprises: an array of a combination of a nanowire core 948 and a shell 950, wherein each nanowire core 948 includes a III-V compound material having a doping of a first conductivity type, and each shell 950 laterally surrounds a respective nanowire core 948 and includes a respective indium gallium nitride active region that emits light at the peak wavelength between 615 nm and 750 nm upon application of an electrical bias thereacross; and a continuous doped III-V compound material layer 952 having a doping of a second conductivity type that is the opposite of the first conductive type and contact outer sidewalls of the shells 950.

In another embodiment shown in FIG. 5D, the at least one light emitting diode comprises: a planar n-doped III-V compound semiconductor material layer (958 or 962) that is located over the continuous indium gallium nitride layer 910; a planar p-doped III-V compound semiconductor material layer (962 or 958) that is located over the continuous indium gallium nitride layer 910; and a respective indium gallium nitride active region 960 located between the planar n-doped III-V compound semiconductor material layer and the planar p-doped III-V compound semiconductor material layer.

In one embodiment, the light emitting device can further comprise: a single crystalline gallium nitride layer 904 located on a single crystalline substrate 902; and a growth mask layer 906 located on the single crystalline gallium nitride layer 904 and including an array of apertures therethrough, wherein an entirety of the continuous indium gallium nitride layer 910 is in epitaxial alignment with the single crystalline gallium nitride layer 904 through each aperture in the array of apertures through the growth mask layer 906.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A method of forming a light emitting device, comprising:
forming a single crystalline gallium nitride layer on a single crystalline substrate;
forming a growth mask layer on the single crystalline gallium nitride layer;
forming an array of apertures through the growth mask layer to physically expose portions of a top surface of the single crystalline gallium nitride layer;
forming Group III nitride nanostructures containing a nitride of at least one Group IIIA element that includes gallium through the array of apertures on the single crystalline gallium nitride layer;
depositing a indium gallium nitride material on the Group III nitride nanostructures until a continuous indium gallium nitride layer that continuously extends over all apertures of the array of apertures is formed; and
forming at least one light emitting diode including an active region that emits light at a peak wavelength in a range from 615 nm to 750 nm over the continuous indium gallium nitride layer.

2. The method of claim 1, wherein:
each of the Group III nitride nanostructures comprise an additional indium gallium nitride material and has a respective pyramidal shape that includes a set of angled facets; and
the set of angle facets contacts a top surface of the growth mask layer.

3. The method of claim 2, wherein the additional indium gallium nitride material has a same material composition as an upper portion of the continuous indium gallium nitride layer, or has a lower atomic concentration of indium than an upper portion of the continuous indium gallium nitride layer.

4. The method of claim 1, wherein each of the Group III nitride nanostructures comprise a gallium nitride material and has a respective pyramidal shape that includes a set of angled facets.

5. The method of claim 4, wherein the set of angle facets contacts a top surface of the growth mask layer.

6. The method of claim 1, wherein each of the Group III nitride nanostructures has a respective nanowire that includes:
substantially vertical sidewalls that extend from the top surface of the single crystalline gallium nitride layer through a respective aperture in the growth mask layer to a top periphery that is raised above a horizontal plane including a top surface of the growth mask layer; and
a set of angled facets that are adjoined to the top periphery of the substantially vertical sidewalls.

7. The method of claim 6, wherein the Group III nitride nanostructures comprise a gallium nitride or indium gallium nitride material.

8. The method of claim 1, wherein the continuous indium gallium nitride layer has a dislocation density that decreases with distance from the growth mask layer and dislocations extend from the bottom surface of the continuous indium gallium nitride layer and terminate within the continuous indium gallium nitride layer

9. The method of claim 1, wherein the at least one light emitting diode comprises:
an array of combinations of a nanowire core and a shell, wherein each nanowire core includes a III-V compound material having a doping of a first conductivity type, and each shell laterally surrounds a respective nanowire core and includes a respective indium gallium nitride active region that emits light at the peak wavelength of 615 nm to 750 nm upon application of an electrical bias thereacross; and
a continuous doped III-V compound material layer having a doping of a second conductivity type that is the opposite of the first conductive type and contact outer sidewalls of the shells.

10. The method of claim 1, wherein the at least one light emitting diode comprises:
a planar n-doped III-V compound semiconductor material layer that is located over the continuous indium gallium nitride layer;
a planar p-doped III-V compound semiconductor material layer that is located over the continuous indium gallium nitride layer; and
a respective indium gallium nitride active region located between the planar n-doped III-V compound semiconductor material layer and the planar p-doped III-V compound semiconductor material layer.

11. A light emitting device comprising:
a continuous indium gallium nitride layer that includes a continuous single crystalline indium gallium nitride material portion, wherein the continuous indium gallium nitride layer has a dislocation density that decreases with distance from a bottom surface of the continuous indium gallium nitride layer and dislocations extend from the bottom surface of the continuous indium gallium nitride layer and terminate within the continuous indium gallium nitride layer; and
at least one light emitting diode including an active region that emits light at a peak wavelength in a range from 615 nm to 750 nm and located over the continuous indium gallium nitride layer.

12. The light emitting device of claim 11, further comprising Group III nitride nanostructures containing a nitride of at least one Group IIIA element that includes gallium, and is located between an upper portion of the continuous indium gallium nitride layer and the bottom surface of the continuous indium gallium nitride layer.

13. The light emitting device of claim 12, wherein each of the Group III nitride nanostructures comprises an indium gallium nitride material having a different composition than an indium gallium nitride material in the upper portion of the continuous indium gallium nitride layer.

14. The light emitting device of claim 12, wherein each of the Group III nitride nanostructures comprises a gallium nitride material and having a pyramidal shape that includes a set of angled facets.

15. The light emitting device of claim 12, wherein each of the Group III nitride nanostructures comprises respective nanowire that includes:
substantially vertical sidewalls that extend from the bottom surface of the continuous indium gallium nitride layer to a top periphery that is raised above bottom surface of the continuous indium gallium nitride layer; and
a set of angled facets that are adjoined to the top periphery of the substantially vertical sidewalls.

16. The light emitting device of claim 15, wherein:
the Group III nitride nanostructures comprise an indium gallium nitride material; and
the indium gallium nitride material has a lower atomic concentration of indium than the upper portion of the continuous indium gallium nitride layer.

17. The light emitting device of claim 15, wherein the Group III nitride nanostructures comprise a gallium nitride material.

18. The light emitting device of claim 11, wherein the at least one light emitting diode comprises:
an array of a combination of a nanowire core and a shell, wherein each nanowire core includes a III-V compound material having a doping of a first conductivity type, and each shell laterally surrounds a respective nanowire core and includes a respective indium gallium nitride active region that emits light at the peak wavelength of 615 nm to 750 nm upon application of an electrical bias thereacross; and
a continuous doped III-V compound material layer having a doping of a second conductivity type that is the opposite of the first conductive type and contact outer sidewalls of the shells.

19. The light emitting device of claim 11, wherein the at least one light emitting diode comprises:
a planar n-doped III-V compound semiconductor material layer that is located over the continuous indium gallium nitride layer;
a planar p-doped III-V compound semiconductor material layer that is located over the continuous indium gallium nitride layer; and
a respective indium gallium nitride active region located between the planar n-doped III-V compound semiconductor material layer and the planar p-doped III-V compound semiconductor material layer.

20. The light emitting device of claim 11, wherein the continuous indium gallium nitride layer has:
a surface roughness of a top surface, measured by AFM on 10×10 micron area, in five locations, of <0.5 nm rms;
an in-plane lattice constant >3.21 Å; and
a dislocation density <1×10⁹ cm⁻².
